(19) United States
(12) Patent Application Publication
(10) Pub. No.: US 2025/0275104 A1
(43) Pub. Date: Aug. 28, 2025

(54) POWER CONVERSION DEVICE

(71) Applicant: Panasonic Automotive Systems Co., Ltd., Kanagawa (JP)

(72) Inventors: Hayata ONAGA, Kanagawa (JP); Yasutoki MANDA, Kanagawa (JP)

(21) Appl. No.: 19/012,433

(22) Filed: Jan. 7, 2025

(30) Foreign Application Priority Data
Feb. 22, 2024 (JP) 2024-025876

(51) Int. Cl. H05K 7/20; H02M 3/00

(52) U.S. Cl. CPC H05K 7/209; H02M 3/003; H05K 7/20254

(57) ABSTRACT

A power conversion device includes a power factor correction circuit includes: a power semiconductor having a heat radiation surface facing a first principal surface of a cooling plate, fixed to the first principal surface so as to exchange heat with the cooling plate, and electrically connected to a drive board; an electrolytic capacitor disposed on an opposite side of the power semiconductor from the cooling plate and a same side of the power semiconductor as the drive board, and electrically connected to the drive board; and a resin mold that is fixed to the first principal surface of the cooling plate, defines a position of the power semiconductor, and is interposed at least between the power semiconductor and the electrolytic capacitor. A second principal surface of the cooling plate is thermally connected to a housing when the power factor correction circuit module is fixed to the housing.

### CROSS-REFERENCE TO RELATED APPLICATIONS

This application is based upon and claims the benefit of priority from Japanese Patent Application No. 2024-025876, filed Feb. 22, 2024, the entire contents of which are incorporated herein by reference.

### FIELD

The present disclosure relates to a power conversion device.

### BACKGROUND

In the related art, in a power conversion device such as a charger mounted on an electric vehicle or the like, for example, there is a demand for miniaturization due to limitation of a mounting space.

For example, Japanese Patent No. 6749428 discloses a technique for miniaturizing an entire device by having a structure in which a power semiconductor, a smoothing capacitor, and a gate drive board are embedded in a power conversion device.

However, when power conversion is performed on power of a large current or a high voltage, the power loss of the power semiconductor increases, and heat generation from the power semiconductor increases. In addition, with the heat generation from the power semiconductor, the influence of the tailgating heat on the surroundings also increases, and thus, for example, there is a possibility that an adverse effect such as deterioration of the capacitor due to heat may occur. Under such circumstances, in a case of using a liquid-cooled type as a heat radiation method, for example, there was a case where a refrigerant stagnates in a flow path and heat cannot be efficiently dissipated depending on the structure of the flow path, for example, a structure in which a flow path in a vertical direction branches from a flow path in a horizontal direction according to the arrangement of a power semiconductor is employed and the like. Therefore, there was a room for improvement in relation to heat radiation from the power semiconductor.

One of the problems to be solved by the present disclosure is to miniaturize a power conversion device in consideration of heat radiation properties.

### SUMMARY

A power conversion device according to the present disclosure includes a housing and a power factor correction circuit module. In the housing, a flow path running in one plane is formed. The power factor correction circuit module is detachably fixed to the housing. The power factor correction circuit module includes a cooling plate, a power semiconductor, an electrolytic capacitor, and a resin mold. The cooling plate has thermal conductivity and is formed in a flat plate shape. The power semiconductor has a heat radiation surface facing a first principal surface of the cooling plate, is fixed to the first principal surface so as to be able to exchange heat with the cooling plate, and is electrically connected to a drive board. The electrolytic capacitor is disposed on an opposite side of the power semiconductor from the cooling plate and a same side of the power semiconductor as the drive board, and is electrically connected to the drive board. The resin mold is fixed to the first principal surface of the cooling plate, defines a position of the power semiconductor, and is interposed at least between the power semiconductor and the electrolytic capacitor. A second principal surface that is a back surface of the first principal surface of the cooling plate is thermally connected to the housing in a state where the power factor correction circuit module is fixed to the housing.

### BRIEF DESCRIPTION OF THE DRAWINGS

FIG. 1 is a diagram illustrating an example of a configuration of a charging system including a power conversion device on which a power factor correction circuit module according to an embodiment is mounted;

FIG. 2 is a perspective view illustrating an example of a configuration of the power factor correction circuit module of FIG. 1; and

FIG. 3 is a cross-sectional view illustrating an example of a configuration of the power factor correction circuit module of FIG. 1.

### DETAILED DESCRIPTION

Hereinafter, embodiments of a power factor correction circuit structure, a power factor correction circuit module, a power conversion device, a vehicle, and a charging system according to the present disclosure will be described with reference to the drawings.

In the description of the present disclosure, components having the same or substantially the same functions as those described above with respect to the previously described drawings are denoted by the same reference numerals, and the description thereof may be appropriately omitted. In addition, even in a case of representing the same or substantially the same portion, the dimensions or ratios may be represented differently from each other depending on the drawings. Furthermore, for example, from a viewpoint of ensuring visibility of the drawings, in the description of each drawing, only main components are denoted by reference numerals, and even components having the same or substantially the same functions as those described above in the previous drawings may not be denoted by reference numerals.

In the description of the present disclosure, components having the same or substantially the same functions may be distinguished and described by adding alphanumeric characters to the end of reference numerals. Alternatively, in a case where a plurality of components having the same or substantially the same functions is not distinguished, the components may be integrated and described by omitting alphanumeric characters added to the end of the reference numerals.

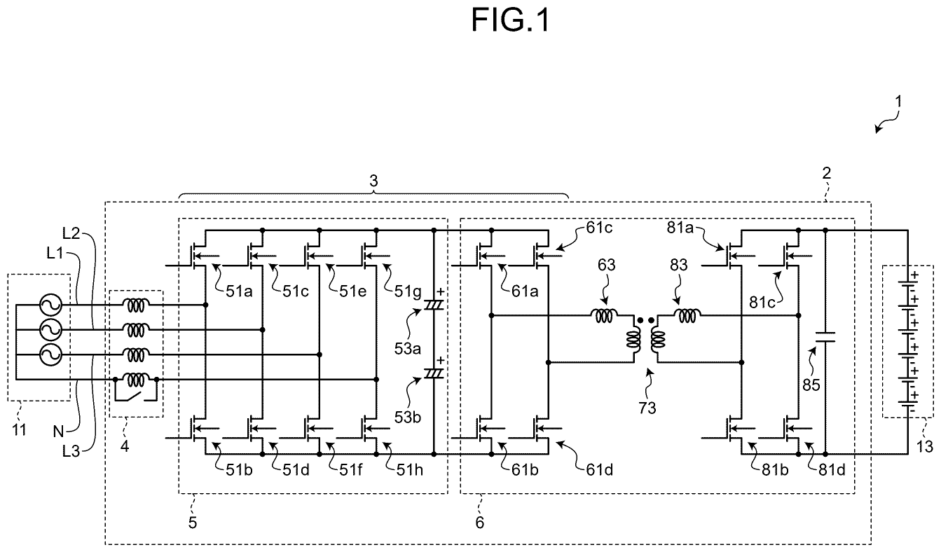

FIG. 1 is a diagram illustrating an example of a configuration of a charging system 1 according to an embodiment. As illustrated in FIG. 1, the charging system 1 includes an AC power source 11, a load 13, and a power conversion device 2. FIG. 1 illustrates a case where a three-phase AC power source (external power source) and a battery are connected to the power conversion device 2 as the AC power source 11 and the load 13.

As an example, the power conversion device 2 according to an embodiment may be mounted on a vehicle as an in-vehicle charger, for example. For example, the power conversion device 2 may be an in-vehicle charger that converts AC power supplied from an external single-phase or three-phase AC power source 11 into DC power and supplies the converted DC power to a load 13 mounted on the vehicle. The load 13 may be, for example, a battery, an inverter, a motor, various electrical components, or the like. In other words, the power conversion device 2 according to the embodiment may be implemented as an in-vehicle charger that converts AC power from the external AC power source 11 into DC power and supplies power to the load 13 such as a battery of a vehicle charged using the DC power.

As the vehicle, for example, various moving bodies configured to be driven or to be able to drive equipment (electrical equipment) by using electric power from a battery, such as passenger car, freight car, van, motorcycle, electric scooter, and the like can be appropriately used. As the electrical equipment, for example, navigation device, audio device, air conditioner, power window, defogger, electronic control unit (ECU), global positioning system (GPS) module, in-vehicle camera, and the like can be used. In addition, the battery of the vehicle only needs to be able to store electric power for driving a traveling motor (main motor), electric components, and the like mounted on the vehicle, and for example, any battery such as lithium ion battery, nickel hydrogen battery, all-solid battery, and the like can be appropriately used. The power conversion device 2 according to the embodiment is not limited to the vehicle, and may be provided in, for example, an aircraft, a game facility, an uninterruptible power source device, and the like.

The AC power source 11 is, for example, any external power source such as power source mounted on a rapid charging facility, commercial power source, and the like. The AC power source 11 is not limited to a single-phase AC power source and a three-phase AC power source (multi-phase AC power source), and a two-phase AC power source (multi-phase AC power source) may be used. In the present embodiment, as the AC power source 11 that supplies AC power to the power conversion device 2, a case where any AC power source 11 of a single-phase or three-phases can be used will be exemplified. That is, in the present embodiment, the power conversion device 2 configured to be operable with both the AC power from the single-phase AC power source 11 and the input of the AC power from the three-phase AC power source 11 will be exemplified.

As illustrated in FIG. 1, the power conversion device 2 is electrically connected to the AC power source 11 via any of a plurality of power source lines L1 to L3 and N. Each of the plurality of power source lines L1 to L3 and N is electrically connected to an input terminal of the power conversion device 2. As an example, the power source line L1 is an electric wire through which a single-phase current from the single-phase AC power source 11 flows. As an example, the power source line L1 is an electric wire through which a U-phase (first phase) current, for example, from the three-phase AC power source 9b flows. As an example, the power source line L2 is an electric wire not electrically connected to the single-phase AC power source 11. As an example, the power source line L2 is an electric wire through which a V-phase (second phase) current, for example, from the three-phase AC power source 11 flows. As an example, the power source line L3 is an electric wire not electrically connected to the single-phase AC power source 11. As an example, the power source line L3 is an electric wire through which a W-phase (third phase) current, for example, from the three-phase AC power source 11 flows. As an example, the power source line N is a neutral line, and is electrically connected to each of the single-phase or three-phase AC power source 11 and a ground potential.

As illustrated in FIG. 1, the power conversion device 2 has a noise filter 4, a power factor correction (PFC) circuit 5, and a DC-DC conversion circuit 6.

The noise filter 4 suppresses (noise removal) entry of noise from the AC power source 11 to the power conversion device 2 and outflow of noise from the power conversion device 2 to the AC power source 11. The noise filter 4 is electrically connected to each of the input terminal of the power conversion device 2 and the power factor correction circuit 5 via the plurality of power source lines L1 to L3 and N. In an example of FIG. 1, the noise filter 4 has a plurality of coils provided in each of the plurality of power source lines L1 to L3 and N. Each of the plurality of coils is, for example, a common mode choke coil, a normal mode choke coil, or the like. In addition, a switch that short-circuits between the input terminal of the power conversion device 2 and the power factor correction circuit 5 when turned on is provided in parallel with the coil provided in the power source line N. This switch operates, for example, under the control of a control circuit (not illustrated) of the power conversion device 2.

Note that, in the noise filter 4, a plurality of X capacitors may be provided between each coil and the input terminal of the power conversion device 2. The plurality of X capacitors is electrically connected between each of the power source lines L1 to L3 and the power source line N (line to line).

Note that, for example, in a subsequent stage of the noise filter 4, an inrush preventing resistor may be provided in each of the plurality of power source lines L1 to L3. This inrush preventing resistor is, for example, an inrush current prevention element such as a temperature fuse resistor, a cement resistor, and a thermistor, and prevents an inrush current from flowing through the power factor correction circuit 5.

The power factor correction circuit 5 rectifies and smooths the AC voltage from the AC power source 11 to generate a DC voltage. As illustrated in FIG. 1, the power factor correction circuit 5 is electrically connected to the noise filter 4 and the DC-DC conversion circuit 6. The power factor correction circuit 5 has MOSFETs 51a, 51c, 51e, and 51g on the high side, MOSFETs 51b, 51d, 51f, and 51h on the low side, and electrolytic capacitors 53a and 53b. Here, MOSFETs 51a to 51h are examples of a plurality of power semiconductors of the power conversion device 2.

The MOSFET 51 rectifies the AC voltage from the AC power source 11. A simple equivalent circuit of each MOSFET 51 is configured using, for example, a switch, a capacitor, and a diode, and operates according to a control signal from a control circuit (not illustrated) of the power conversion device 2. For example, in the simple equivalent circuit, the switch, the capacitor, and the diode are electrically connected in parallel. For example, in the MOSFET 51 on the high side, an anode and a cathode of the diode are electrically connected to an input side (AC power source 11 side) and an output side (load 13 side) of each MOSFET 51, respectively. On the other hand, in the MOSFET 51 on the low side, the anode and the cathode of the diode are electrically connected to the output side and the input side of each MOSFET 51, respectively. In each MOSFET 51, a switch is turned on/off at a timing corresponding to a control signal from a control circuit (not illustrated) of the power conversion device 2 to switch communication/division. In each MOSFET 51, charges from an AC power source are accumulated in a capacitor during a period when the switch is turned off (division), and a potential difference occurs between terminals on the input side and the output side. Note that, in the present embodiment, the matter that the internal switch is turned on/off is expressed as that the MOSFET 51 is turned on/off.

The input side and the output side of each of the MOSFET 51 on the high side are electrically connected to the coil of the noise filter 4 and the input side of each MOSFET 61 on the high side of the DC-DC conversion circuit 6, respectively. In addition, the input side and the output side of each MOSFET 51 on the high side are electrically connected to the coil of the noise filter 4 and the input side of each of the MOSFET 61 on the low side of the DC-DC conversion circuit 6, respectively.

The MOSFETs 51a and 51b are examples of a pair of power semiconductors, related to the power source line L1, that is, corresponding to a specific phase among a plurality of phases of the AC power source 11. Specifically, the MOSFETs 51a and 51b rectify a single-phase current from the single-phase AC power source 11 flowing through the power source line L1 or, for example, a U-phase (first phase) current from the three-phase AC power source 11. MOSFETs 51c and 51d are examples of a pair of power semiconductors, related to the power source line L2, that is, corresponding to another phase of the specific phase among the plurality of phases of the AC power source 11. Specifically, the MOSFETS 51c and 51d rectify a single-phase current from the single-phase AC power source 11 flowing through the power source line L2, or, for example, a V-phase (second phase) current from the three-phase AC power source 11. The MOSFETs 51e and 51f are examples of a pair of power semiconductors, related to the power source line L3, that is, corresponding to another phase of the specific phase among the plurality of phases of the AC power source 11. Specifically, the MOSFETs 51e and 51f rectify a single-phase current from the single-phase AC power source 11 flowing through the power source line L3, or, for example, a W-phase (third phase) current from the three-phase AC power source 11. The MOSFETs 51g and 51h are examples of a pair of power semiconductors, related to the power source line N, that is, corresponding to a neutral line. Specifically, the MOSFETs 51g and 51h form an electric circuit for returning the single-phase current flowing through the power source lines L1 to L3 from the single-phase AC power source 11 toward the AC power source 11.

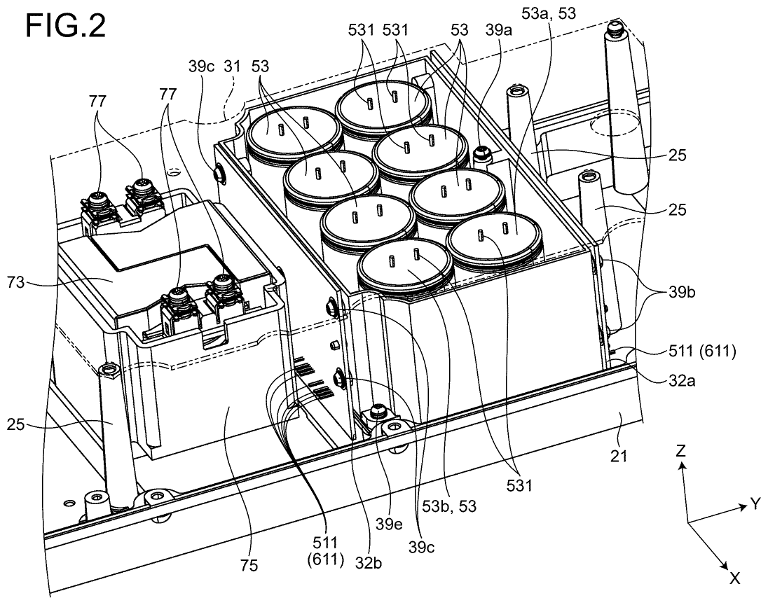

An electrolytic capacitor 53 smooths the current rectified by the MOSFET 51. The electrolytic capacitor 53 is an output capacitor of the power factor correction circuit 5. In addition, the electrolytic capacitor 53 can be expressed as an input capacitor of the DC-DC conversion circuit 6. FIG. 1 illustrates electrolytic capacitors 53a and 53b as the electrolytic capacitor 53. The electrolytic capacitors 53a and 53b are electrically connected between the output side (load 13 side) of the MOSFET 51 on the high side and the output side (load 13 side) of the MOSFET 51 on the low side. Note that the electrolytic capacitors 53a and 53b may be implemented by one electrolytic capacitor, or may be implemented by three or more of a plurality of electrolytic capacitors. For example, FIG. 2 exemplifies a case of being implemented by eight electrolytic capacitors 53.

The DC-DC conversion circuit 6 converts a DC voltage generated by the power factor correction circuit 5 to an AC voltage again, and then rectifies and smooths the AC voltage to generate a DC voltage of any set voltage. As illustrated in FIG. 1, the DC-DC conversion circuit 6 is electrically connected to each of the power factor correction circuit 5 and the output terminal of the power conversion device 2. The DC-DC conversion circuit 6 has MOSFETs 61a to 61d on the primary side, a coil 63 on the primary side, a transformer 73, MOSFETs 81a to 81d on the secondary side, a coil 83 on the secondary side, and an output capacitor 85. Note that each of the coil 63 on the primary side and the coil 83 on the secondary side may be substituted by the leakage inductance of the transformer 73. Here, the MOSFETS 61a to 61d on the primary side are examples of a plurality of power semiconductors of the power conversion device 2.

The MOSFETs 61a to 61d on the primary side and the coil 63 convert a DC voltage from the electrolytic capacitor 53 as an input capacitor into an AC voltage by a switching operation of the MOSFET 61 under the control of a control circuit (not illustrated) of the power conversion device 2. That is, the MOSFETs 61a to 61d on the primary side and the coil 63 constitute a DC-AC inverter circuit. The simple equivalent circuit of each MOSFET 61 has, for example, the same configuration as that of each MOSFET 51 of the power factor correction circuit 5. For example, in the MOSFET 61 on the high side, an anode and a cathode of the diode are electrically connected to an output side (load 13 side) and input side (AC power source 11 side) of each MOSFET 61, respectively. On the other hand, in the MOSFET 61 on the low side, the anode and the cathode of the diode are electrically connected to the input side and the output side of each MOSFET 61, respectively.

The input side of each MOSFET 61 on the high side is electrically connected to the output side of each MOSFET 51 on the high side of the power factor correction circuit 5. In addition, the input side of each MOSFET 61 on the low side is electrically connected to the output side of each MOSFET 51 on the low side of the power factor correction circuit 5. In addition, the output side of the MOSFETs 61a and 61b is electrically connected to one terminal on the primary side of the transformer 73 via the coil 63. In addition, the output side of the MOSFETs 61c and 61d is electrically connected to the other terminal on the primary side of the transformer 73, that is, the side opposite to the coil 63.

The transformer 73 is a potential transformer that transmits energy of the single-phase AC voltage generated by the MOSFETs 61a to 61d on the primary side and the coil 63 to the secondary side.

The MOSFETs 81a to 81d on the secondary side and the coil 83 rectify the single-phase AC voltage transmitted by the transformer 73 by a switching operation of the MOSFET 81 under control of the control circuit (not illustrated) of the power conversion device 2. The simple equivalent circuit of each MOSFET 81 has, for example, the same configuration as that of each MOSFET 51 of the power factor correction circuit 5. For example, in the MOSFET 81 on the high side, an anode and a cathode of the diode are electrically connected to an input side (AC power source 11 side) and an output side (load 13 side) of each MOSFET 61, respectively. On the other hand, in the MOSFET 81 on the low side, the anode and the cathode of the diode are electrically connected to the output side and the input side of each MOSFET 81, respectively.

The input side of the MOSFETs 81a and 81b are electrically connected to one terminal on the secondary side of the transformer 73 via the coil 83, that is, one terminal having the same polarity as the terminal on the primary side to which the coil 63 is connected in the example of FIG. 1. In addition, the output side of the MOSFETs 81c and 81d is electrically connected to the other terminal on the secondary side of the transformer 73, that is, the side opposite to the coil 83. In addition, the output sides of each of MOSFETs 81 on the high side and the low side are electrically connected to a pair of output terminals of the power conversion device 2.

The output capacitor 85 smooths the current rectified by the MOSFET 81. The output capacitor 85 is electrically connected between an output side (load 13 side) of the MOSFET 81 on the high side and an output side (load 13 side) of the MOSFET 81 on the low side. That is, the output capacitor 85 is electrically connected between the pair of output terminals of the power conversion device 2.

Note that a control circuit (not illustrated) of the power conversion device 2 has, for example, at least one processor and at least one memory, and may have a hardware configuration using a normal computer. As this processor, for example, a central processing unit (CPU) can be used. The processor executes, for example, a program to integrally control the operation of the control circuit and implement various functions of the control circuit. Note that the control circuit causes, for example, the processor to load a program stored in a read only memory (ROM) and the like into a random access memory (RAM), and execute the loaded program, and thus the control circuit may implement various functions of the control circuit, or a dedicated hardware circuit (semiconductor integrated circuit and the like) may implement some or all of the various functions.

Note that the control circuit of the power conversion device 2 may be implemented by a domain control unit (DCU) such as an electronic control unit (ECU) provided inside a vehicle or a cockpit domain controller (CDC) obtained by integrating a plurality of ECUs; or a computer such as an on board unit (OBU). In addition, the control circuit may transmit and receive information with another ECU mounted on the vehicle or an external power source (AC power source 11) connected to the vehicle via an in-vehicle network including a controller area network (CAN) inside the vehicle, Ethernet (registered trademark), or a universal serial bus (USB) (registered trademark), or may communicate with an information processing device outside the vehicle via a network such as the Internet.

As illustrated in FIG. 1, the power factor correction circuit 5 and the MOSFET 61 of the DC-DC conversion circuit 6 constitute a power factor correction circuit module 3 according to the embodiment. That is, the power conversion device 2 according to the embodiment mounts the power factor correction circuit module 3. Note that the power factor correction circuit module 3 may include other circuit configurations such as the noise filter 4 and the coil 63, for example.

Here, the power factor correction circuit structure of the power factor correction circuit module 3 according to the present disclosure will be described in detail with reference to the drawings.

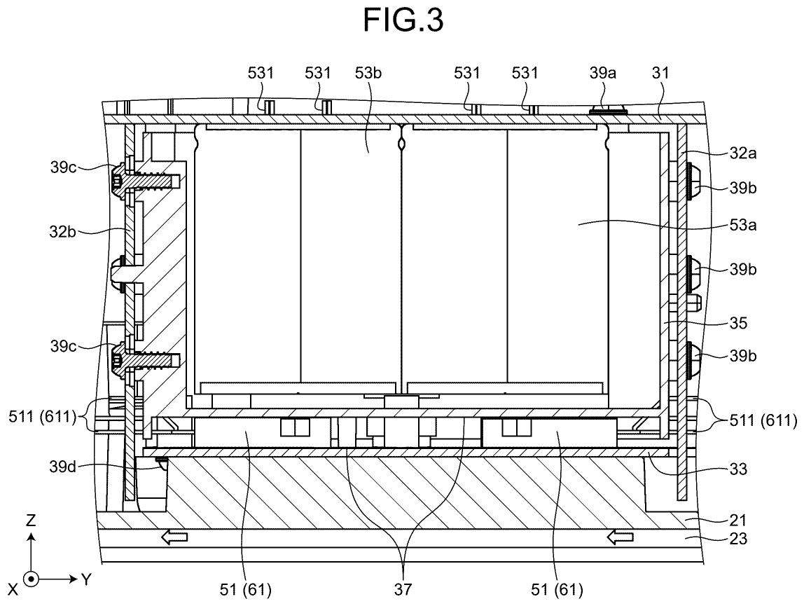

FIG. 2 is a perspective view illustrating an example of a configuration (power factor correction circuit structure) of the power factor correction circuit module 3 of FIG. 1. FIG. 2 illustrates the appearance of the power factor correction circuit module 3 of the power conversion device 2 and the vicinity thereof. FIG. 3 is a cross-sectional view illustrating an example of a configuration (power factor correction circuit structure) of the power factor correction circuit module 3 of FIG. 1. FIG. 3 illustrates a cross-section of the power factor correction circuit module 3 and the vicinity thereof when a Y-Z plane passing through a plurality of fixing members 39c provided on an X+ side of a relay board 32b of FIG. 2 is viewed from the X+ side. Note that in FIGS. 2 and 3, some or all of other configurations of the power conversion device 2 is omitted.

As illustrated in FIGS. 2 and 3, the power factor correction circuit module 3 is disposed above (Z+ side) a housing 21 of the power conversion device 2. As illustrated in FIG. 2, the power factor correction circuit module 3 is detachably fixed on the housing 21 by a fixing member 39e such as a screw, for example.

In addition, as illustrated in FIGS. 2 and 3, a drive board 31 is disposed above (Z+ side) the power factor correction circuit module 3. The drive board 31 is a main board of the power conversion device 2. Each unit of the power conversion device 2 is electrically connected to the drive board 31 directly or via another component. The drive board 31 is detachably fixed to a support unit 25 of the housing 21 by a fixing member (not illustrated) such as a screw.

Note that the drive board 31 may be a component of the power factor correction circuit module 3, or may be a component of the power conversion device 2 outside the power factor correction circuit module 3.

The housing 21 is a flat plate-shaped member extending along the X-Y plane. Note that the housing 21 is formed by, for example, die casting, but may be formed of iron or may not be made of an alloy. In addition, the housing 21 may be made of another metal material as long as heat from components such as the power factor correction circuit module 3 disposed on the housing 21 can be transported to a coolant flowing through a flow path 23 inside the housing 21.

In addition, the housing 21 is provided with a liquid-cooling type cooling mechanism using a coolant such as antifreeze liquid as a working fluid. Specifically, as illustrated in FIG. 3, the flow path 23 of the coolant is formed inside the housing 21. In the housing 21 according to the embodiment, the flow path 23 extends in a direction (for example, horizontal direction) along the X-Y plane. That is, the flow path 23 that runs in one plane is formed inside the housing 21.

The flow path 23 may be branched in at least two directions along the X-Y plane. On the other hand, the flow path 23 according to the embodiment is not branched in a direction along a Z direction. In other words, in the housing 21 according to the embodiment, in a case where there is an intersection where the flow paths 23 in at least two directions intersect, each of the flow paths 23 extends in the direction along the X-Y plane from the intersection, but does not extend in the direction along the Z direction. As described above, the power conversion device 2 according to the present disclosure can constitute a cooling mechanism of the entire system by the flow path 23 running only in one plane (X-Y plane).

The power factor correction circuit module 3 and the housing 21 are thermally connected. Here, being thermally connected means being configured to be able to exchange heat. Note that heat transport between the power factor correction circuit module 3 and the housing 21 is implemented by, for example, heat conduction, but may be performed in other forms in addition to or instead of heat conduction. In addition, heat transport between the power factor correction circuit module 3 and the housing 21 may be performed via other components.

In addition, as illustrated in FIG. 2, other components of the power conversion device 2 such as the transformer 73 are also disposed on the housing 21. The transformer 73 is covered with a casing 75. The casing 75 is formed of, for example, metal, and shields electromagnetic noise from the transformer 73. The transformer 73 and the drive board 31 are electrically connected by, for example, a fixing member 77 such as a screw or soldering.

Generally, in the power conversion device, the transformer 73 is a component (large component) larger than other components. Therefore, the height (length in Z direction) of the support unit 25 of the housing 21 that supports the drive board 31 is determined such that the transformer 73 is accommodated between the housing 21 and the drive board 31. That is, the height (size in Z direction) of the power conversion device 2 depends on the distance between the housing 21 and the drive board 31 via the transformer 73. In other words, in a case where the distance (size in Z direction) between the housing 21 and the drive board 31 is defined based on the size of a large component such as the transformer 73, there is a surplus in height at the disposition position of other components of the large component, that is, at a position different from the large component in an X-Y direction.

Under such circumstances, the power conversion device 2 according to the present disclosure has the power factor correction circuit module 3 in which some of the other components among the other plurality of components of the transformer 73 are modularized. In addition, the power factor correction circuit module 3 is inserted between the housing 21 and the drive board 31 of which interval is determined in accordance with the transformer 73. That is, the power factor correction circuit module 3 according to the present disclosure is configured to be smaller in the height direction (Z direction) than other large components of the power conversion device 2, thereby implementing miniaturization of the power conversion device 2.

As illustrated in FIGS. 2 and 3, the power factor correction circuit module 3 further has relay boards 32a and 32b, an insulating heat radiation board 33, and a resin mold 35.

As illustrated in FIG. 3, the drive board 31 is detachably fixed to the resin mold 35 by a fixing member 39a such as a screw. That is, the resin mold 35 supports the drive board 31.

Each of the relay boards 32a and 32b is electrically connected to the drive board 31. A wiring pattern is provided on the relay board 32. The relay board 32 electrically connects electrically connected components to the drive board 31 via the wiring pattern. For example, some components of the power factor correction circuit module 3 (power conversion device 2) are electrically connected to the drive board 31 via the relay board 32. As illustrated in FIG. 3, the relay board 32a is detachably fixed to the resin mold 35 by a fixing member 39b such as a screw. In addition, the relay board 32b is detachably fixed to the resin mold 35 by the fixing member 39c such as a screw. That is, the resin mold 35 supports each of the relay boards 32a and 32b.

Note that the electrical connection between the drive board 31 and the relay board 32 may be implemented by soldering, or may be implemented by detachable connection via a connector.

As illustrated in FIGS. 2 and 3, the insulating heat radiation board 33 is disposed below (Z−side) the resin mold 35. The resin mold 35 is fixed to a surface (first principal surface) of the insulating heat radiation board 33 on the drive board 31 side by a fixing member (not illustrated) such as a screw and an adhesive. In other words, the resin mold 35 supports the insulating heat radiation board 33.

The insulating heat radiation board 33 is a member formed in a flat plate shape extending along the X-Y plane. The insulating heat radiation board 33 has thermal conductivity (preferably high thermal conductivity) and electrical insulation properties. Specifically, the insulating heat radiation board 33 only needs to be capable of transporting heat in a thickness direction (Z direction), and is, for example, a metal plate, but may be formed of a non-metal. Here, the insulating heat radiation board 33 according to the embodiment is an example of a cooling plate.

In addition, an insulating layer having electrical insulation properties is formed on an outer surface of the insulating heat radiation board 33. That is, the insulating layer is provided between each of the MOSFETs 51 and 61 and the insulating heat radiation board 33. Note that the insulating layer on the outer surface of the insulating heat radiation board 33 may be formed by applying coating of a material having electrical insulation properties, or may be formed by providing a sheet-like member having electrical insulation properties on the outer surface. Note that the insulating heat radiation board 33 may be a plate-like member formed of a material having thermal conductivity and electrical insulation properties.

At least the housing 21 side (Z−side) of the insulating heat radiation board 33 is formed in a shape conforming to the shape of the disposition position of the power factor correction circuit module 3 above (Z+side) the housing 21. Here, a surface of the insulating heat radiation board 33 on the housing 21 side (Z−side) is a cooling surface of the power factor correction circuit module 3. In other words, in the power conversion device 2, the cooling surface of the power factor correction circuit module 3 extends along the plane (X-Y plane) on which the flow path 23 of the housing 21 is provided. That is, the cooling surface of the power factor correction circuit module 3 is thermally connected to the housing 21, so that heat generated inside can be dissipated to the housing 21.

As an example, the power factor correction circuit module 3 is fixed to the housing 21 by fixing the insulating heat radiation board 33 to the housing 21 with the fixing member 39e. That is, in a state where the power factor correction circuit module 3 is fixed to the housing 21, the surface (second principal surface) of the insulating heat radiation board 33 on the housing 21 side is thermally connected to the housing 21. Here, the surface of the insulating heat radiation board 33 on the housing 21 side is a back surface of the surface (first principal surface) of the insulating heat radiation board 33 on the resin mold 35 side.

As illustrated in FIG. 3, the MOSFETs 51 and 61 (power semiconductors) of the power factor correction circuit 5 and the DC-DC conversion circuit 6 are disposed on the surface (first principal surface) of the insulating heat radiation board 33 on the resin mold 35 side. Each of the plurality of MOSFETs 51 and 61 is fixed to the insulating heat radiation board 33 by a fixing member (not illustrated) such as an adhesive or an adhesive sheet. The fixing member may be any fixing member as long as the fixing member is formed of at least a material having thermal conductivity. Note that the fixing member may have electrical insulation properties, and in this case, the insulating heat radiation board 33 may not have electrical insulation properties.

The cooling surface of each of the plurality of MOSFETs 51 and 61 faces a surface of the insulating heat radiation board 33 on the resin mold 35 side, and is thermally connected to the insulating heat radiation board 33. That is, the heat radiation path of each of the plurality of MOSFETs 51 and 61 is a path in the Z direction from each of the cooling surfaces to the flow path 23 via the insulating heat radiation board 33 and the housing 21. As described above, each of the MOSFETs 51 and 61 is fixed to the surface of the insulating heat radiation board 33 on the resin mold 35 side so that heat can be exchanged between the heat radiation surface and the insulating heat radiation board 33.

Here, as illustrated in FIG. 3, each of the plurality of MOSFETs 51 and 61 is flatly placed on the insulating heat radiation board 33. Here, being flatly placed means that the heat radiation surface of each of the plurality of MOSFETs 51 and 61 is opposed to the surface of the insulating heat radiation board 33 on the resin mold 35 side, and is disposed on the insulating heat radiation board 33.

Each of the plurality of MOSFETs 51 and 61 is disposed in a gap 37 formed between the insulating heat radiation board 33 and the resin mold 35. In other words, each of the plurality of MOSFETs 51 and 61 is disposed below (Z-side) the electrolytic capacitor 53 via the resin mold 35. For example, each of the plurality of MOSFETs 51 and 61 is disposed immediately below the electrolytic capacitor 53. That is, an upper side (Z+side) of each of the plurality of MOSFETs 51 and 61 is covered with the resin mold 35. Each of the plurality of MOSFETs 51 and 61 is defined (positioned) at a position (for example, position in X-Y direction) on the insulating heat radiation board 33 by the resin mold 35.

In addition, each of leads 511 and 611 of the plurality of MOSFETs 51 and 61 is electrically connected to the drive board 31. In the configuration illustrated in FIGS. 2 and 3, the leads 511 and 611 of each of the plurality of MOSFETs 51 and 61 is electrically connected to one of the relay boards 32a and 32b, for example, by soldering.

As described above, by providing the relay board 32 on the power factor correction circuit module 3, some of components of the power conversion device 2 such as the MOSFETs 51 and 61 (power semiconductors) can be electrically connected to the drive board 31 via the relay board 32, and thus a degree of freedom of the disposition can be enhanced. For example, in a case where the MOSFETs 51 and 61 are directly connected to the drive board 31, there is a limitation in the installation position of the MOSFETs 51 and 61 due to the arrangement of the wire for the connection. On the other hand, in the power factor correction circuit module 3 according to the present disclosure, due to indirect connection to the drive board 31 via the relay board 32, a degree of freedom of the disposition can be enhanced.

Note that in some or all of each of the leads 511 and 611 of the plurality of MOSFETs 51 and 61, the leads 511 and 611 may, for example, extend to the drive board 31 in the Z direction. That is, each of the plurality of MOSFETs 51 and 61 may be electrically connected to the drive board 31 without using the relay board 32. In this case, some or all of the relay board 32 may not be provided.

Note that any one of the relay boards 32a and 32b may not be provided depending on the number and disposition of the plurality of MOSFETs 51 and 61. That is, the number of relay boards 32 may be one. On the other hand, the number of relay boards 32 may be three or more.

As an example, the relay board 32 may be provided on at least one side in the Y direction of the resin mold 35. As an example, the relay board 32 may be provided on at least one side in the X direction of the resin mold 35. That is, the relay board 32 may be provided on at least one side surface portion that extends from a bottom surface portion (part on Z−side) of the resin mold 35 toward the drive board 31 and covers the electrolytic capacitor 53.

As an example, the relay board 32 is provided in at least the bottom surface portion (some of Z−side) of the resin mold 35 interposed between the MOSFETs 51 and 61 and the electrolytic capacitor 53. For example, the relay board 32 may be provided on the side opposite to the insulating heat radiation board 33 of each of the plurality of MOSFETS 51 and 61. For example, the relay board 32 may be provided between each of the plurality of MOSFETs 51 and 61 and the resin mold 35. For example, the relay board 32 may be provided below (Z−side) the electrolytic capacitor 53 inside the resin mold 35. In this case, the relay board 32 may be accommodated inside the resin mold 35 or may protrude from the resin mold 35.

As described above, according to the configuration in which the relay board 32 is provided on the side opposite to the insulating heat radiation board 33 of each of the plurality of MOSFETs 51 and 61, the degree of freedom of the disposition of the plurality of MOSFETs 51 and 61 can be further enhanced. In addition, according to the configuration, radiation heat (air heat) from the plurality of MOSFETs 51 and 61 to other components such as the electrolytic capacitor 53 can be reduced by the relay board 32.

In addition, the relay board 32 is not limited to a flat plate-shaped board, and may be a board having an L-shaped cross-section. That is, the relay board 32 may be formed into a shape such as an L-shaped angle (L-shaped angle-iron). That is, the relay board 32 may be a board having at least one L-shaped cross-section supported by at least two of the bottom surface portion and at least one side surface portion of the resin mold 35. The L-shaped relay board 32 may be provided over two side surfaces (X direction and Y direction) of the resin mold 35, or may be provided over a side surface (X direction or Y direction) and a bottom surface (Z−side) of the resin mold 35.

In addition, the electrolytic capacitor 53 of the power factor correction circuit 5 is disposed on the side (Z+side) of the resin mold 35 opposite to the MOSFETs 51 and 61, that is, inside the resin mold 35 in the configuration illustrated in FIGS. 2 and 3. In other words, the electrolytic capacitor 53 is disposed on the drive board 31 side of the MOSFETs 51 and 61, which is opposite to the insulating heat radiation board 33.

A lead 531 of the electrolytic capacitor 53 is electrically connected to the drive board 31. For example, the electrolytic capacitor 53 is fixed to the drive board 31 by soldering or the like, and is supported by the drive board 31. As an example, the electrolytic capacitor 53 is disposed in midair from the drive board 31 toward the resin mold 35. In addition, the electrolytic capacitor 53 may be held by the resin mold 35, or a position thereof may be defined (positioned) with respect to the drive board 31. Note that the electrolytic capacitor 53 may be held by the resin mold 35.

As described above, the resin mold 35 is interposed at least between the MOSFETs 51 and 61 and the electrolytic capacitor 53, and radiation heat from the plurality of MOSFETs 51 and 61 and the electrolytic capacitor 53 can be reduced. More specifically, in the power factor correction circuit module 3 according to the present disclosure, the MOSFETs 51 and 61 and the electrolytic capacitor 53 are covered with the resin mold 35. That is, in the power factor correction circuit module 3 according to the present disclosure, the resin mold 35 plays a role of holding and positioning the MOSFETs 51 and 61 and a role of insulating the electrolytic capacitor 53.

Note that the resin mold 35 may further perform positioning of other components such as the electrolytic capacitor 53, not limited to the MOSFETs 51 and 61. In other words, the resin mold 35 defines (positions) the position of at least each of the MOSFETs 51 and 61.

Note that the gap 37 between the insulating heat radiation board 33 and the resin mold 35 or the gap between the resin mold 35 and the electrolytic capacitor 53 may be filled with a heat radiation buffer such as a gap filler having at least heat radiation properties (thermal conductivity). That is, a heat radiation buffer such as a gap filler may be used as the heat capacity. Accordingly, the heat radiation performance from the power factor correction circuit module 3 can be further enhanced. The gap filler preferably further has electrical insulation properties.

A reflective or absorptive heat shielding layer that hinders heat transport to the electrolytic capacitor 53 via the resin mold 35 may be formed on a side of the resin mold 35 facing each of the plurality of MOSFETs 51 and 61. In addition, a reflective heat shielding layer, for example, that hinders heat transfer from the outside may be formed on an outer surface of the electrolytic capacitor 53. These heat shielding layers may be formed, for example, by applying a heat shielding coating to the outer surface of the resin mold 35. Accordingly, heat radiation performance from the power factor correction circuit module 3 can be further enhanced, or deterioration by heat of the electrolytic capacitor 53 can be suppressed.

Note that the power conversion device 2 according to the present disclosure can be expanded by mounting a plurality of power factor correction circuit modules 3 in parallel. That is, the power conversion device 2 according to the present disclosure has extensibility by modularizing the MOSFET 61 of the power factor correction circuit 5 and the DC-DC conversion circuit 6. For example, the power conversion device 2 can increase the output (kW number) by electrically connecting a plurality of power factor correction circuit modules 3, of a power amount of power conversion, that is, of the number corresponding to the output amount (kW number) of the DC voltage in parallel, that is, by increasing the number of modules.

As described above, in the power conversion device 2 according to the present disclosure, a power factor correction circuit structure required for power conversion is modularized. Specifically, in the power factor correction circuit module 3 according to the present disclosure, each of the plurality of MOSFETs 51 and 61 can be flatly placed on the insulating heat radiation board 33. Therefore, in the housing 21 of the power conversion device 2, the flow path 23 inside the housing 21 can be formed as a flow path running only in the horizontal direction (X-Y direction), and the stagnation of the working fluid (coolant) can be suppressed. In addition, in the power factor correction circuit module 3 according to the present disclosure, the degree of freedom of the MOSFETs 51 and 61 can be enhanced by using the relay board 32. In addition, by making the power factor correction circuit module 3 according to the present disclosure more compact in a height direction than a large component such as the transformer 73, the entirety of the power conversion device 2 can be miniaturized.

According to the above-described at least one embodiment, it is possible to miniaturize a power conversion device in consideration of heat radiation properties.

According to the present disclosure, it is possible to miniaturize a power conversion device in consideration of heat radiation properties.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

### Supplement

The following techniques are disclosed by the above description of the embodiments.
(1)
A power conversion device including:
a housing in which a flow path running in one plane is formed; and
a power factor correction circuit module detachably fixed to the housing, wherein
the power factor correction circuit module includes:
   a cooling plate having thermal conductivity and formed in a flat plate shape;
   a power semiconductor having a heat radiation surface facing a first principal surface of the cooling plate, fixed to the first principal surface so as to be able to exchange heat with the cooling plate, and electrically connected to a drive board;
   an electrolytic capacitor disposed on an opposite side of the power semiconductor from the cooling plate and a same side of the power semiconductor as the drive board, and electrically connected to the drive board; and
   a resin mold that is fixed to the first principal surface of the cooling plate, defines a position of the power semiconductor, and is interposed at least between the power semiconductor and the electrolytic capacitor, and
a second principal surface that is a back surface of the first principal surface of the cooling plate is thermally connected to the housing in a state where the power factor correction circuit module is fixed to the housing.
(2)
The power conversion device according to (1),
wherein a lead of the power semiconductor extends to the drive board.
(3)
The power conversion device according to (1), wherein
the power factor correction circuit module further includes a relay board electrically connected to the drive board,
the resin mold supports the relay board, and
the power semiconductor is electrically connected to the relay board and is connected to the drive board via the relay board.
(4)
The power conversion device according to (3), wherein
the resin mold has a bottom surface portion interposed between the power semiconductor and the electrolytic capacitor, and at least one side surface portion extending from the bottom surface portion toward the drive board and covering the electrolytic capacitor, and
the relay board is at least one board supported by at least one of the bottom surface portion and the at least one side surface portion of the resin mold.
(5)
The power conversion device according to (4),
wherein the relay board is a board that is held by at least two of the bottom surface portion and the at least one side surface portion of the resin mold and has at least one L-shaped cross-section.
(6)
The power conversion device according to (3),
wherein the relay board is at least one board that is held by the bottom surface portion of the resin mold interposed between the power semiconductor and the electrolytic capacitor.
(7)
The power conversion device according to any one of (1) to (6), wherein
the power semiconductor is disposed in a gap between the first principal surface of the cooling plate and the resin mold, and
the gap is filled with a heat radiation buffer.
(8)
The power conversion device according to any one of (1) to (7),
wherein the power factor correction circuit module further includes the drive board.
(9)
The power conversion device according to any one of (1) to (8), wherein
the power factor correction circuit module includes a number of power factor correction circuit modules, the number corresponding to a power amount of power to be converted.
(10)
The power conversion device according to any one of (1) to (9), further including
a transformer that is fixed to the housing and electrically connected to the drive board,
wherein the power factor correction circuit module is smaller than the transformer in a direction from the housing toward the drive board.
(11)
A vehicle including:
a power conversion device according to any one of (1) to (10), which converts AC power from an external AC power source to DC power; and
a battery charged using the DC power converted by the power conversion device.

What is claimed is:

1. A power conversion device comprising:
a housing in which a flow path running in one plane is formed; and
a power factor correction circuit module detachably fixed to the housing, wherein
the power factor correction circuit module includes:
a cooling plate having thermal conductivity and formed in a flat plate shape;
a power semiconductor having a heat radiation surface facing a first principal surface of the cooling plate, fixed to the first principal surface so as to be able to exchange heat with the cooling plate, and electrically connected to a drive board;
an electrolytic capacitor disposed on an opposite side of the power semiconductor from the cooling plate and a same side of the power semiconductor as the drive board, and electrically connected to the drive board; and
a resin mold that is fixed to the first principal surface of the cooling plate, defines a position of the power semiconductor, and is interposed at least between the power semiconductor and the electrolytic capacitor, and
a second principal surface that is a back surface of the first principal surface of the cooling plate is thermally connected to the housing in a state where the power factor correction circuit module is fixed to the housing.

2. The power conversion device according to claim 1,
wherein a lead of the power semiconductor extends to the drive board.

3. The power conversion device according to claim 1, wherein
the power factor correction circuit module further includes a relay board electrically connected to the drive board,
the resin mold supports the relay board, and
the power semiconductor is electrically connected to the relay board and is connected to the drive board via the relay board.

4. The power conversion device according to claim 3, wherein
the resin mold has a bottom surface portion interposed between the power semiconductor and the electrolytic capacitor, and at least one side surface portion extending from the bottom surface portion toward the drive board and covering the electrolytic capacitor, and
the relay board is at least one board supported by at least one of the bottom surface portion and the at least one side surface portion of the resin mold.

5. The power conversion device according to claim 4,
wherein the relay board is a board that is held by at least two of the bottom surface portion and the at least one side surface portion of the resin mold and has at least one L-shaped cross-section.

6. The power conversion device according to claim 3,
wherein the relay board is at least one board that is held by the bottom surface portion of the resin mold interposed between the power semiconductor and the electrolytic capacitor.

7. The power conversion device according to claim 1, wherein
the power semiconductor is disposed in a gap between the first principal surface of the cooling plate and the resin mold, and
the gap is filled with a heat radiation buffer.

8. The power conversion device according to claim 1,
wherein the power factor correction circuit module further includes the drive board.

9. The power conversion device according to claim 1, wherein
the power factor correction circuit module includes a number of power factor correction circuit modules, the number corresponding to a power amount of power to be converted.

10. The power conversion device according to claim 1, further comprising
a transformer that is fixed to the housing and electrically connected to the drive board,
wherein the power factor correction circuit module is smaller than the transformer in a direction from the housing toward the drive board.
